(19) United States
(12) Patent Application Publication
(10) Pub. No.: US 2026/0198312 A1
(43) Pub. Date: Jul. 9, 2026

(54) SEMICONDUCTOR DEVICE AND METHOD OF MAKING THE SAME

(71) Applicants: University of Virginia Patent Foundation, Charlottesville, VA (US); THE GOVERNMENT OF THE UNITED STATES OF AMERICA, AS REPRESENTED BY THE SECRETARY OF THE NAVY, Arlington, VA (US); UNIVERSITY OF MARYLAND, COLLEGE PARK, College Park, MD (US); THE REGENTS OF THE UNIVERSITY OF CALIFORNIA, Oakland, CA (US); UNIVERSITY OF SOUTH CAROLINA, Columbia, SC (US)

(72) Inventors: Karl D. Hobart, Washington, DC (US); Travis J. Anderson, Washington, DC (US); Marko J. Tadjer, Washington, DC (US); Alan G. Jacobs, Washington, DC (US); Tatyana I. Feygelson, Washington, DC (US); Bradford B. Pate, Washington, DC (US); Samuel Graham, JR., Riverdale Park, MD (US); Henry Aller, Des Moines, WA (US); Patrick Hopkins, Charlottesville, VA (US); Mark Goorsky, Los Angeles, CA (US); Asif Khan, Irmo, SC (US)

(21) Appl. No.: 19/482,976

(22) PCT Filed: May 25, 2024
(86) PCT No.: PCT/US2024/031167

§ 371 Date: Nov. 10, 2025

Related U.S. Application Data
(60) Provisional application No. 63/504,488, filed on May 26, 2023.

(51) Int. Cl. H10W 40/20; H10D 30/01; H10D 30/47; H10D 62/824; H10W 40/00; H10W 40/25

(52) U.S. Cl. CPC H10W 40/242; H10D 30/015; H10D 30/475; H10W 40/03; H10W 40/233; H10W 40/254; H10D 62/824

(57) ABSTRACT

In one aspect, the disclosure relates to a device comprising a plurality of semiconductor layers; a phonon bridge layer formed on the plurality of semiconductor layers; a gate electrode set into the phonon bridge layer and in contact with a surface of the plurality of semiconductor layers; and a diamond layer formed over the phonon bridge layer. The phonon bridge layer can include materials that have a speed of sound in-between the speed of sound for the diamond layer and the speed of sound of the semiconductor layer that is in contact with the phonon bridge layer. In one aspect, the device is a transistor, such as a high electron mobility transistor. The disclosure, in another aspect, relates to methods of making the devices as disclosed herein.

### CROSS-REFERENCE TO RELATED APPLICATIONS

This application claims the benefit of U.S. Provisional Application No. 63/504,488, filed on May 26, 2023, which is incorporated herein by reference in its entirety.

### STATEMENT REGARDING FEDERALLY SPONSORED RESEARCH

This disclosure was made with U.S. Government support under grant N00014-18-1-2429 awarded by the Office of Naval Research. The U.S. government has certain rights in the disclosure.

### BACKGROUND

Extreme bandgap (EBG) semiconductors have garnered attention for their potential applications in high voltage, high power, and high-temperature power electronic devices. However, optimal device performance and power output in these devices, such as high electron mobility transistors (HEMTs), hinges on efficient thermal management. The inherent low thermal conductivity of some EBG semiconductors and significant thermal resistance of adjacent interfaces within a transistor often result in a significant accumulation of heat within the device. One strategy for addressing heat removal is the implementation of top-side heat spreading layers, which offering alternative pathways for heat dissipation. The intrinsic high thermal conductivity of diamond makes it a good candidate for top-side heat spreading layers. However, integrating diamond top-side heat spreaders on transistors can often have a negative affect on the device's overall electrical performance.

Therefore, there is a need for electronic devices, such as transistors, that are able to operate at high power with good electrical performance and improved thermal management. These needs and other needs are satisfied by the present disclosure.

### SUMMARY

In accordance with the purpose(s) of the disclosure, as embodied and broadly described herein, the disclosure, in one aspect, relates to a device comprising a plurality of semiconductor layers; a phonon bridge layer formed on the plurality of semiconductor layers; a gate electrode set into the phonon bridge layer and in contact with a surface of the plurality of semiconductor layers; and a diamond layer formed over the phonon bridge layer. The phonon bridge layer can include materials that have a speed of sound in-between the speed of sound for the diamond layer and the speed of sound of the semiconductor layer that is in contact with the phonon bridge layer. In one aspect, the device is a transistor, such as a high electron mobility transistor. The disclosure, in another aspect, relates to methods of making the devices as disclosed herein.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described aspects are usable in all aspects of the disclosure taught herein. Furthermore, the individual features of the dependent claims, as well as all optional and preferred features and modifications of the described aspects are combinable and interchangeable with one another.

### BRIEF DESCRIPTION OF THE FIGURES

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A shows representative sample structures investigated in this study with nominal thickness values.

FIG. 1B shows an example data set and fitting of hybrid steady-state thermoreflectance (SSTR)/time-domain thermoreflectance (TDTR) data.

FIG. 2 shows representative two-dimensional contour plots for TBR_{Di/AlGaN} and K_{Di} shown for TDTR and SSTR, and the newly discovered hybrid technique of TDTR/SSTR. For each contour plot, the regions which provide a good fit to the experimental data (i.e., residual value <0.01) are shaded and labeled. Notably, for TDTR and SSTR individually, the good fit region does not end. This is because alone each method is incapable of measuring TB_{RDi/AlGaN} and K_{Di} for the samples. However, for TDTR/SSTR hybrid technique contour plot, there is an overlap region (shaded and indicated by an arrow). By fitting to both TDTR and SSTR datasets simultaneously, an overlapping region (where both datasets are fit well) is created, bounding the possible extracted values for TBR_{Di/AlGaN} and K_{Di} in the experiment. As such, the hybrid fitting technique is what enables the measurement of the samples to be possible.

FIG. 3 shows representative SSTR/TDTR measured results for TBR_{Di/AlGaN} for each of the different samples. Direct growth is the case of no interlayer, with diamond grown directly on the AlGaN top layer. All carbide interlayers are noticed to significantly reduce TBR_{Di/AlGaN} from the Direct Growth case, with B₄C interlayer providing the lowest TBR_{Di/AlGaN} of 3.4 m²K/GW, a new record for Diamond/AlGaN interfaces.

FIGS. 4A-4D shows representative graphs displaying the phonon density of states versus phonon frequency for the materials in the samples: FIG. 4A, a comparison between crystalline AlGaN and crystalline Diamond; FIG. 4B, crystalline AlGaN, crystalline Diamond, amorphous SiC, and amorphous B₄C, where B₄C and SiC both provide vibrational bridging via introducing intermediate phonon modes between AlGaN and Diamond; FIG. 4C, a comparison between the crystalline and amorphous B₄C; and FIG. 4D, a comparison between crystalline and amorphous SiC.

FIGS. 5A-5F shows representative STEM images of the samples investigated in this study. (FIG. 5A) and (FIG. 5B) show the zoomed-out STEM image for 65% and 83% Aluminum concentration AlGaN samples. (FIG. 5B) STEM image shows the Direct Growth sample (no interlayer) where there is visible structural disorder at the diamond/AlGaN interface. (FIG. 5C, FIG. 5E, and FIG. 5F) STEM images of three interlayers, with the thickness of the interlayer shown. Notably, all interlayers are amorphous.

FIG. 6 shows the measured value of TBRDi/AlGaN using various combinations of thermal measurement techniques, with the error bars quantifying the contour uncertainty associated with each fit.

FIGS. 7A-7B show examples of an AlGaN-based transistor without (FIG. 7A) and with (FIG. 7B) a heat spreader.

FIG. 8A shows simulations of operating temperature increases for a transistor without a heat spreader using various various substrates and semiconductors. The power density is 2 W/mm.

FIG. 8B shows simulations of operating temperature increases for a transistor with a heat spreader using various various substrates and semiconductors. The power density is 2 W/mm.

FIG. 8C shows simulations of operating temperature increases for the transistor of FIG. 8B with an Al₂O₃ substrate and an AlN/GaN digital alloy (DA) semiconductor, and the influence of heat sink thermal conductivity (KHs) and thermal barrier coating (TBC) on the transistor.

FIG. 9 shows a representative example structure of a transistor with diamond growth.

FIGS. 10A-10B show representative rough and disordered GaN/Diamond interfaces following a diamond growth process using hydrogen plasma.

FIG. 11 shows representative atomic force microscopy images of a B₄C layer on a silicon substrate.

FIG. 12 shows representative atomic force microscopy images of a SiC layer on a silicon substrate.

FIG. 13 shows representative atomic force microscopy images of a SiC/B₄C layer on a silicon substrate.

Additional advantages of the disclosure will be set forth in part in the description which follows, and in part will be obvious from the description, or can be learned by practice of the disclosure. The advantages of the disclosure will be realized and attained by means of the elements and combinations particularly pointed out in the appended claims. It is to be understood that both the foregoing general description and the following detailed description are exemplary and explanatory only and are not restrictive of the disclosure, as claimed.

### DETAILED DESCRIPTION

Many modifications and other aspects disclosed herein will come to mind to one skilled in the art to which the disclosed compositions and methods pertain having the benefit of the teachings presented in the foregoing descriptions and the associated drawings. Therefore, it is to be understood that the disclosures are not to be limited to the specific aspects disclosed and that modifications and other aspects are intended to be included within the scope of the appended claims. The skilled artisan will recognize many variants and adaptations of the aspects described herein. These variants and adaptations are intended to be included in the teachings of this disclosure and to be encompassed by the claims herein.

Although specific terms are employed herein, they are used in a generic and descriptive sense only and not for purposes of limitation.

As will be apparent to those of skill in the art upon reading this disclosure, each of the individual aspects described and illustrated herein has discrete components and features which may be readily separated from or combined with the features of any of the other several aspects without departing from the scope or spirit of the present disclosure.

Any recited method can be carried out in the order of events recited or in any other order that is logically possible. That is, unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is no way intended that an order be inferred, in any respect. This holds for any possible non-express basis for interpretation, including matters of logic with respect to arrangement of steps or operational flow, plain meaning derived from grammatical organization or punctuation, or the number or type of aspects described in the specification.

All publications mentioned herein are incorporated herein by reference to disclose and describe the methods and/or materials in connection with which the publications are cited. The publications discussed herein are provided solely for their disclosure prior to the filing date of the present application. Nothing herein is to be construed as an admission that the present disclosure is not entitled to antedate such publication by virtue of prior disclosure. Further, the dates of publication provided herein can be different from the actual publication dates, which can require independent confirmation.

While aspects of the present disclosure can be described and claimed in a particular statutory class, such as the system statutory class, this is for convenience only and one of skill in the art will understand that each aspect of the present disclosure can be described and claimed in any statutory class.

It is also to be understood that the terminology used herein is for the purpose of describing particular aspects only and is not intended to be limiting. Unless defined otherwise, all technical and scientific terms used herein have the same meaning as commonly understood by one of ordinary skill in the art to which the disclosed compositions and methods belong. It will be further understood that terms, such as those defined in commonly used dictionaries, should be interpreted as having a meaning that is consistent with their meaning in the context of the specification and relevant art and should not be interpreted in an idealized or overly formal sense unless expressly defined herein.

Prior to describing the various aspects of the present disclosure, the following definitions are provided and should be used unless otherwise indicated. Additional terms may be defined elsewhere in the present disclosure.

### A. DEFINITIONS

As used herein, “comprising” is to be interpreted as specifying the presence of the stated features, integers, steps, or components as referred to, but does not preclude the presence or addition of one or more features, integers, steps, or components, or groups thereof. Moreover, each of the terms “by”, “comprising,” “comprises”, “comprised of,” “including,” “includes,” “included,” “involving,” “involves,” “involved,” and “such as” are used in their open, non-limiting sense and may be used interchangeably. Further, the term “comprising” is intended to include examples and aspects encompassed by the terms “consisting essentially of” and “consisting of.” Similarly, the term “consisting essentially of” is intended to include examples encompassed by the term “consisting of.

As used herein, the term “and/or” includes any and all combinations of one or more of the associated listed items. Expressions such as “at least one of,” when preceding a list of elements, modify the entire list of elements and do not modify the individual elements of the list.

As used herein, nomenclature for compounds, including organic compounds, can be given using common names, IUPAC, IUBMB, or CAS recommendations for nomenclature. When one or more stereochemical features are present, Cahn-Ingold-Prelog rules for stereochemistry can be employed to designate stereochemical priority, E/Z specification, and the like. One of skill in the art can readily ascertain the structure of a compound if given a name, either by systemic reduction of the compound structure using naming conventions, or by commercially available software, such as CHEMDRAW™ (Cambridgesoft Corporation, U.S.A.).

Reference to “a” chemical compound refers to one or more molecules of the chemical compound rather than being limited to a single molecule of the chemical compound. Furthermore, the one or more molecules may or may not be identical, so long as they fall under the category of the chemical compound. Thus, for example, “a” chemical compound is interpreted to include one or more molecules of the chemical, where the molecules may or may not be identical (e.g., different isotopic ratios, enantiomers, and the like).

As used in the specification and the appended claims, the singular forms “a,” “an” and “the” include plural referents unless the context clearly dictates otherwise. Thus, for example, reference to “a layer” or “an electrode,” includes, but is not limited to, two or more such layers or electrodes, and the like.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

When a range is expressed, a further aspect includes from the one particular value and/or to the other particular value. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, the terms “about,” “approximate,” “at or about,” and “substantially” mean that the amount or value in question can be the exact value or a value that provides equivalent results or effects as recited in the claims or taught herein. That is, it is understood that amounts, sizes, formulations, parameters, and other quantities and characteristics are not and need not be exact but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In such cases, it is generally understood, as used herein, that “about” and “at or about” mean the nominal value indicated±10% variation unless otherwise indicated or inferred. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

As used herein, the terms “optional” or “optionally” means that the subsequently described event or circumstance can or cannot occur, and that the description includes instances where said event or circumstance occurs and instances where it does not.

Unless otherwise specified, temperatures referred to herein are based on atmospheric pressure (i.e. one atmosphere).

### B. ABBREVIATIONS

HEMT—High Electron Mobility Transistor
TBR—thermal boundary resistance
EBG—Extreme Bandgap
TDTR—time-domain thermoreflectance
MOCVD—metal-organic chemical vapor deposition
MPCVD—microwave plasma chemical vapor deposition

### C. INTRODUCTION

In one aspect, the disclosure relates to devices and methods of making devices that address the need for high power electronics that have efficient thermal management. More specifically, in one aspect, the present disclosure relates to transistors, such as HEMTs, and methods of making transistors that comprise a diamond heat-spreader layer and demonstrate good electrical performance and low TBRs at the diamond/semiconductor interface. The disclosed devices incorporate thin barrier layers between the diamond and semiconductor and show significant reduction in TBR at the diamond/semiconductor interface compared to like devices without barrier layers. Furthermore, the barrier layers are not significantly damaged or etched during the diamond deposition process.

EBG semiconductors, like Group III-nitride materials such as AlₓGa₁₋ₓN (x>0.5), have garnered attention for their potential applications in high voltage, high power, and high-temperature power electronics. [1-4] However, optimal device performance and power output in these devices, such as HEMTs, hinges on efficient thermal management. [5, 6] The inherent low thermal conductivity of EBG semiconductors and significant thermal resistance of adjacent interfaces within the 3D stack structure of a transistor results in the heat generated within the channel to accumulate near the gate region. [7-9] AlGaN, for example, has a thermal conudcitivty of approximately 8-10 W/mK.

In order to address inefficient substrate-side heat removal towards a heat-sunk device package, top-side heat spreading layers can be integrated atop the device, offering alternative pathways for heat dissipation in close proximity to the hot spot. [5, 6] The intrinsic high thermal conductivity of diamond makes it a prime candidate for top-side heat spreading layers. For example, Malakoutian et al. demonstrated for a GaN-on-Al₂O₃ device, that the inclusion of 650 nm polycrystalline diamond grown on-top of the device could reduce channel temperatures by ≤42% at 6 W/mm. [10] Arivazhagan et al. similarly showed with thermal simulations that a GaN-on-Si HEMT device could match the operating temperatures of an equivalent GaN-on-SiC device if a diamond top-side heat spreader was implemented. [11] However, achieving diamond integration without affecting the device's electrical performance is challenging.

Integrating diamond top-side heat spreaders on HEMTs presents several challenges. In AlGaN HEMTs, the top surface can be etched or damaged by the hydrogen used in the MPCVD growth of diamond films, especially when the growth temperature exceeds 600° C. [12] Babchenko et al. demonstrated that a 60-minute hydrogen plasma treatment on an AlGaN/GaN heterostructure resulted in an increase in gate leakage current by approximately six orders of magnitude, significantly impacting the electrical properties of the device.

### D. TRANSISTORS COMPRISING A DIAMOND HEAT SPREADER

Disclosed herein is a device, such as a transistor, comprising a plurality of semiconductor layers; a phonon bridge layer formed on the plurality of semiconductor layers; a gate electrode set into the phonon bridge layer and in contact with a surface of the plurality of semiconductor layers; and a diamond layer formed over the phonon bridge layer. In a further aspect, the phonon bridge layer comprises materials that have a speed of sound in-between the speed of sound for the diamond layer and the speed of sound of the semiconductor layer that is in contact with the phonon bridge layer. The presence of the phonon bridge layer can reduce the TBR at the diamond layer/semiconductor layers interface, improving dissipation of heat throughout the device. In one aspect, the device can have a TBR at the diamond layer/semiconductor layers interface of less than about 20 m²K/GW, less than about 15 m²K/GW, less than about 10 m²K/GW, or less than about 5 m²K/GW. In another aspect, the device can have a TBR at the diamond layer/semiconductor layers interface of from about 1 m²K/GW to about 20 m²K/GW, about 1 m²K/GW to about 15 m²K/GW, about 1 m²K/GW to about 10 m²K/GW, about 5 m²K/GW to about 20 m²K/GW, or about 5 m²K/GW to about 15 m²K/GW.

The phonon bridge layer can be comprised of a plurality of sub-layers. In one aspect, the phonon bridge layer includes from 1 to 4 sub-layers. The phonon bridge layer and/or sub-layers thereof can be comprised of a metal carbide, a metal boride, or a graded material thereof. In a further aspect, wherein the phonon bridge layer comprises silicon carbide, boron carbide, beryllium carbide, aluminum carbide, magnesium carbide, aluminum boride, magnesium boride, beryllium boride, titanium boride, or a graded material thereof. A graded material or graded layer, as used herein, refers to both a continuously graded material or layer and a step-graded material or layer.

In one aspect, the phonon bridge layer has a thickness of from about 0.1 nm to about 50 nm, about 0.1 nm to about 40 nm, about 0.1 nm to about 30 nm, about 0.1 nm to about 25 nm, about 0.1 nm to about 10 nm, or about 0.1 nm to about 5 nm. A sub-layer of the phonon bridge layer can have a thickness of from about 0.1 nm to about 50 nm, about 0.1 nm to about 40 nm, about 0.1 nm to about 30 nm, about 0.1 nm to about 25 nm, about 0.1 nm to about 10 nm, about 0.1 nm to about 5 nm, about 0.1 nm to about 3 nm, about 1 nm to about 10 nm, about 1 nm to about 5 nm, or about 1 nm to about 3 nm. The surface of the phonon bridge layer can be relatively smooth, with a surface roughness of less than about 0.25 nm, less than about 0.20 nm, or less than about 0.15 nm. In another aspect, the phonon bridge layer can have a surface roughness of about 0.01 nm to about 0.25 nm, about 0.01 nm to about 0.20 nm, about 0.01 nm to about 0.15 nm, about 0.50 nm to about 0.20 nm, or about 0.50 nm to about 0.15 nm. Surface roughness is quantified by the deviation of the normal vector direction of the actual surface from its ideal form. A smoother surface has a smaller deviation.

The diamond layer can be comprised of nanocrystalline diamond. In one aspect, the diamond layer has a thickness of from about 0.01 μm to about 500 μm, about 0.01 μm to about 100 μm, about 0.01 μm to about 10 μm, about 0.05 μm to about 500 μm, about 0.05 μm to about 100 μm, about 0.05 μm to about 50 μm, about 0.05 μm to about 10 μm, about 0.05 μm to about 5 μm, about 0.05 μm to about 1 μm, about 0.1 μm to about 100 μm, about 0.1 μm to about 10 μm, or about 0.1 μm to about 1 μm.

The plurality of semiconductor layers can include at least a substrate layer and a channel layer, where the channel layer is formed on top of the substrate layer. The semiconductor layers can further include a nucleation layer, formed between the substrate layer and channel layer. Additionally, the semiconductor layers can include a barrier layer formed on top of the channel layer.

In one aspect, the substrate layer can be comprised of a material such as Al₂O₃, AlN, SiC, Si, GaN, BN, InN, Ga₂O₃, or a combination thereof.

The channel layer can be comprised of a material such as a Group III-nitride or Group III-nitride alloy. For example, the channel layer can be comprised of a material selected from BN, AlN, GaN, InN, BAlN, AlGaN, InAlN, InGaN, ScAlN, InAlGaN, a graded material thereof, or a combination thereof. In a further aspect, the channel layer can be comprised of AlGaN in the form AlₓGa₁₋ₓN, where x is from 0.50 to about 0.95 or from about 0.65 to about 0.85. The channel layer can have a thickness of from about 0.01 μm to about 20 μm, about 0.01 μm to about 15 μm, about 0.01 μm to about 10 μm, about 0.01 μm to about 5 μm, or about 0.01 μm to about 1 μm.

In one aspect, the nucleation layer is a graded layer comprising a Group III-nitride or Group III-nitride alloy. For example, the nucleation layer can be a graded layer comprised of a material selected from BN, AlN, GaN, InN, BAlN, AlGaN, InAlN, InGaN, ScAlN, InAlGaN, or a combination thereof. The nucleation layer can have a thickness of from about 1 nm to about 100 nm, about 1 nm to about 50 nm thick, about 1 nm to about 25 nm, or about 1 nm to about 10 nm.

The barrier layer can be comprised of a Group III-nitride or Group III-nitride alloy. For example, the barrier layer can be comprised of a material selected from AlN, AlGaN, InGaN, InAlN, ScAlN, BAlN, InAlGaN, a graded material thereof, or a combination thereof. The barrier layer can have a thickness of from about 5 nm to about 100 nm, about 10 nm to about 90 nm, or about 25 nm to about 75 nm.

In one aspect, the gate electrode can be comprised of a metal, such as nickel, platinum, or a combination thereof. In one aspect, the gate electrode can be formed with regrowth of a p-type GaN (p-GaN) layer and an ohmic metal to the p-GaN using a low work function metal (e.g., titanium, vanadium, and the like).

In one aspect, the gate electrode of the device or transistor can comprise a metal nitride alloy material. In one aspect, the metal nitride alloy material can be a binary or a ternary metal nitride alloy material. In a further aspect, the metal nitride alloy material is a transition metal nitride material. The metal nitride alloy material can include titanium nitride, titanium carbon nitride, titanium niobium nitride, titanium aluminum nitride, tantalum nitride, tungsten nitride, niobium nitride, niobium titanium nitride, molybdenum nitride, tantalum nitride (Ta₃N₅), zirconium nitride (Zr₃N₄), zirconium titanium nitride, hafnium nitride (Hf₃N₄), copper nitride (Cu₃N), or any combination thereof. In a further aspect, the metal nitride alloy material can be a nitrogen-rich titanium nitride (TiNₓ) with a ratio of nitrogen to titatium atoms that is greater than 1.0.

The device can further include a source electrode and a gate electrode set into the phonon bridge layer, where both the source electrode and gate electrode are in contact with at least one of the plurality of semiconductor layers. In one aspect, the source and gate electrodes are in contact with the channel layer. In another aspect, the source and gate electrodes are in contact with the barrier layer.

### E. METHODS OF PREPARING THE DISCLOSED TRANSISTORS

Also disclosed herein are methods for producing a device disclosed herein, comprising: growing a plurality of semiconductor epitaxial layers on a substrate; depositing a gate material on the plurality of semiconductor epitaxial layers; depositing a phonon bridge layer on the plurality of semiconductor epitaxial layers; and growing a diamond layer on the phonon bridge layer.

The epitaxial layers can be grown using methods including, but not limited to, metal-organic chemical vapor deposition, hydride vapor-phase epitaxy, or molecular beam epitaxy.

Growing the diamond layer can further comprise: ultrasonic deposition of diamond nano crystals, forming a diamond seeded layer; and growing the diamond layer from the diamond seeded layer by chemical vapor deposition (e.g., laser-plasma chemical vapor deposition, microwave-plasma chemical vapor deposition, or hot filament chemical vapor deposition). As an example, the diamond layer can be grown at temperatures ranging from about 400° C. to about 800° C. and at pressures ranging from about 5 Torr to about 30 Torr. Temperature, pressure, and other conditions can be selected depending on the substrate material, the desired diamond film properties, and/or the growth reactor system. When growing the diamond by microwave-plasma chemical vapor deposition, the plasma power can range from, in one aspect, about 600 W to about 2500 W.

As a general example, the plurality of semiconductor layers can be grown on a substrate, for example by MOCVD, hydride vapor-phase epitaxy, molecular-beam epitaxy, or atomic layer epitaxy. Optionally, a nucleation layer can first be grown on the substrate, using a like method, prior to growing the remaining semiconductor layers. The gate electrode or material for forming the gate electrode can be deposited next. In one aspect, the gate can be deposited by atomic layer deposition, chemical vapor deposition, physical vapor deposition (e.g., sputtering), or metal organic vapor deposition. A phonon bridge layer can be deposited on top of the semiconductor layers by methods including, but not limited to, sputtering, chemical vapor deposition, atomic layer deposition, pulsed laser deposition, plasma-enhanced chemical vapor deposition, or electron-beam evaporation. In one aspect, the phonon bridge layers are formed on top of the semiconductor layers but not on top of the gate electrode. A diamond thin-film layer can then be grown on top of the phonon bridge layer and gate electrode. In one aspect, the diamond layer is a high-thermal conductivity diamond. Forming the diamond layer can comprise a seeding step performed by ultrasonic deposition of diamond nano crystals. Following seeding, the diamond layer can be grown from the seeds by chemical vapor deposition (e.g., laser-plasma chemical vapor deposition, microwave-plasma chemical vapor deposition, or hot filament chemical vapor deposition).

The top surface of the plurality of semiconductor layers can be damaged by the diamond growth process. In one aspect, the phonon bridge layer can provide a protective barrier to prevent hydrogen plasma-induced damage to the semiconductor layer surface.

Additionally, disclosed herein is a fitting scheme that leverages multiple thermal measurement techniques (SSTR and TDTR), enabling the accurate probing of buried thermal interface resistances—a task challenging to achieve with a singular measurement setup alone. The hybrid technique of SSTR-TDTR capitalizes on the strengths of both measurement techniques.

A challenge associated with thermal characterization of the effectiveness of phonon bridge layers between diamond and the semiconductor is the limitation imposed by the thermal penetration depth and contour uncertainty. The buried nature of this interface, situated beneath the diamond, poses difficulties for thermal characterization techniques such TDTR, which can become insensitive to thermal resistances at depths of hundreds of nanometers, exceeding the measurement technique's thermal penetration depth. Moreover, there is the issue of contour uncertainty, wherein an increase in the number of unknown parameters being fitted leads to higher uncertainty in their fitted values. To determine the TBR of the diamond/semiconductor interface, the TBR of the transducer/diamond interface must be fit with the thermal conductivity of the grown diamond. Consequently, measuring buried thermal resistances without encountering significant uncertainty in the obtained value presents a challenge. However, this contour uncertainty can be mitigated by employing multiple measurement techniques with varying thermal penetration depths.

### F. ASPECTS

The following listing of exemplary aspects supports and is supported by the disclosure provided herein.

Aspect 1. A device, comprising a plurality of semiconductor layers; a phonon bridge layer formed on the plurality of semiconductor layers; a gate electrode set into the phonon bridge layer and in contact with a surface of the plurality of semiconductor layers; and a diamond layer formed over the phonon bridge layer; wherein the phonon bridge layer comprises materials that have a speed of sound in-between the speed of sound for the diamond layer and the speed of sound of the semiconductor layer that is in contact with the phonon bridge layer.

Aspect 2. The device of Aspect 1, wherein the phonon bridge layer is from about 0.1 nm to about 50 nm thick.

Aspect 3. The device of Aspect 1, wherein the phonon bridge layer is from about 0.1 nm to about 25 nm thick.

Aspect 4. The device of Aspect 1, wherein the phonon bridge layer is from about 0.1 nm to about 10 nm thick.

Aspect 5. The device of Aspect 1, wherein the phonon bridge layer is from about 0.1 nm to about 5 nm thick.

Aspect 6. The device of any one of Aspects 1-5, wherein the phonon bridge layer comprises a metal carbide, a metal boride, or a graded material thereof.

Aspect 7. The device of any one of Aspects 1-5, wherein the phonon bridge layer comprises silicon carbide, boron carbide, beryllium carbide, aluminum carbide, magnesium carbide, aluminum boride, magnesium boride, beryllium boride, titanium boride, or a graded material thereof.

Aspect 8. The device of any one of Aspects 1-7, wherein the phonon bridge layer comprises from 1 to 4 sub-layers.

Aspect 9. The device of Aspect 8, wherein each sub-layer is individually from about 0.1 to about 50 nm thick.

Aspect 10. The device of Aspect 8, wherein each sub-layer is individually from about 0.1 to about 25 nm thick.

Aspect 11. The device of Aspect 8, wherein each sub-layer is individually from about 0.1 to about 10 nm thick.

Aspect 12. The device of Aspect 8, wherein each sub-layer is individually from about 0.1 to about 5 nm thick.

Aspect 13. The device of Aspect 8, wherein each sub-layer is individually from about 0.1 to about 3 nm thick.

Aspect 14. The device of Aspect 8, wherein each sub-layer is individually from about 1 to about 5 nm thick.

Aspect 15. The device of any one of Aspects 8-14, wherein each sub-layer individually comprises a metal carbide, a metal boride, or a graded material thereof.

Aspect 16. The device of any one of Aspects 8-14, wherein each sub-layer individually comprises silicon carbide, boron carbide, beryllium carbide, aluminum carbide, magnesium carbide, aluminum boride, magnesium boride, beryllium boride, titanium boride, or a graded material thereof.

Aspect 17. The device of any one of Aspects 1-16, wherein the diamond layer comprises nanocrystalline diamond.

Aspect 18. The device of any one of Aspects 1-17, wherein the diamond layer is greater than or equal to 0.01 μm thick.

Aspect 19. The device of any one of Aspects 1-17, wherein the diamond layer is from about 0.01 μm to about 500 μm thick.

Aspect 20. The device of any one of Aspects 1-17, wherein the diamond layer is from about 0.01 μm to about 100 μm thick.

Aspect 21. The device of any one of Aspects 1-17, wherein the diamond layer is from about 0.01 μm to about 10 μm thick.

Aspect 22. The device of any one of Aspects 1-21, wherein the plurality of semiconductor layers comprises at least a substrate layer and a channel layer.

Aspect 23. The device of Aspect 22, wherein the substrate layer comprises Al₂O₃, AlN, SiC, Si, GaN, BN, InN, Ga₂O₃, or a combination thereof.

Aspect 24. The device of Aspect 22 or aspect 23, wherein the channel layer comprises a Group III-nitride or alloy thereof.

Aspect 25. The device of Aspect 22 or aspect 23, wherein the channel layer comprises a Group III-nitride or alloy thereof selected from BN, AlN, GaN, InN, BAlN, AlGaN, InAlN, InGaN, ScAlN, InAlGaN, a graded material thereof, or a combination thereof.

Aspect 26. The device of Aspect 22 or aspect 23, wherein the channel layer comprises AlGaN in the form AlₓGa₁₋ₓN, wherein x is from 0.50 to about 0.95.

Aspect 27. The device of Aspect 22 or aspect 23, wherein the channel layer comprises AlGaN in the form AlₓGa₁₋ₓN, wherein x is from about 0.65 to about 0.85.

Aspect 28. The device of any one of Aspects 22-27, wherein the channel layer is from about 0.01 μm to about 20 μm thick.

Aspect 29. The device of any one of Aspects 22-27, wherein the channel layer is from about about 0.01 μm to about 10 μm thick.

Aspect 30. The device of any one of Aspects 22-27, wherein the channel layer is from about about 0.01 μm to about 1 μm thick.

Aspect 31. The device of any one of Aspects 22-30, wherein the plurality of semiconductor layers further comprises a nucleation layer between the substrate layer and the channel layer.

Aspect 32. The device of Aspect 31, wherein the nucleation layer is a graded layer comprising a Group III-nitride or alloy thereof selected from from BN, AlN, GaN, InN, BAlN, AlGaN, InAlN, InGaN, ScAlN, InAlGaN, or a combination thereof.

Aspect 33. The device of Aspect 31 or Aspect 32, wherein the nucleation layer is from about 1 nm to about 100 nm thick.

Aspect 34. The device of Aspect 31 or Aspect 32, wherein the nucleation layer is from about 1 nm to about 50 nm thick.

Aspect 35. The device of any one of Aspects 1-34, wherein the plurality of semiconductor layers further comprises a barrier layer on top of the channel layer.

Aspect 36. The device of Aspect 35, wherein the barrier layer comprises a Group III-nitride or alloy thereof selected from AlN, AlGaN, InGaN, InAlN, ScAlN, BAlN, InAlGaN, a graded material thereof, or a combination thereof.

Aspect 37. The device of Aspect 35 or Aspect 36, wherein the barrier layer is from about 5 nm to about 100 nm thick.

Aspect 38. The device of Aspect 35 or Aspect 36, wherein the barrier layer is from about 25 nm to about 75 nm thick.

Aspect 39. The device of any one of Aspects 1-38, wherein the thermal boundary resistance of the diamond/semiconductor layers interface is less than about 15 m2K/GW.

Aspect 40. The device of any one of Aspects 1-38, wherein the thermal boundary resistance of the diamond/semiconductor layers interface is less than about 10 m2K/GW.

Aspect 41. The device of any one of Aspects 1-38, wherein the thermal boundary resistance of the diamond/semiconductor layers interface is from about 1 m2K/GW to about 15 m²K/GW.

Aspect 42. The device of any one of Aspects 1-38, wherein the thermal boundary resistance of the diamond/semiconductor layers interface is from about 1 m2K/GW to about 10 m2K/GW.

Aspect 43. A device, comprising a plurality of semiconductor layers, comprising a substrate layer, a channel layer, and a barrier layer, wherein the channel layer is between the substrate layer and the barrier layer; a phonon bridge layer formed on the barrier layer; a gate electrode set into the phonon bridge layer and in contact with at least one of the plurality of semiconductor layers; a drain electrode set into the phonon bridge layer and in contact with at least one of the plurality of semiconductor layers; a source electrode set into the phonon bridge layer and in contact with at least one of the plurality of semiconductor layers; a diamond layer formed over the phonon bridge layer; wherein the phonon bridge layer comprises materials that have a speed of sound in-between the speed of sound for the diamond layer and the speed of sound for the channel layer.

Aspect 44. The device of Aspect 43, wherein the phonon bridge layer is from about 0.1 nm to about 50 nm thick.

Aspect 45. The device of Aspect 43, wherein the phonon bridge layer is from about 0.1 nm to about 25 nm thick.

Aspect 46. The device of Aspect 43, wherein the phonon bridge layer is from about 0.1 nm to about 10 nm thick.

Aspect 47. The device of Aspect 43, wherein the phonon bridge layer is from about 0.1 nm to about 5 nm thick.

Aspect 48. The device of any one of Aspects 43-47, wherein the phonon bridge layer comprises a metal carbide, a metal boride, or a graded material thereof.

Aspect 49. The device of any one of Aspects 43-47, wherein the phonon bridge layer comprises silicon carbide, boron carbide, beryllium carbide, aluminum carbide, magnesium carbide, aluminum boride, magnesium boride, beryllium boride, titanium boride, or a graded material thereof.

Aspect 50. The device of any one of Aspects 43-49, wherein the phonon bridge layer comprises from 1 to 4 sub-layers.

Aspect 51. The device of Aspect 50, wherein each sub-layer is individually from about 0.1 to about 50 nm thick.

Aspect 52. The device of Aspect 50, wherein each sub-layer is individually from about 0.1 to about 25 nm thick.

Aspect 53. The device of Aspect 50, wherein each sub-layer is individually from about 0.1 to about 10 nm thick.

Aspect 54. The device of Aspect 50, wherein each sub-layer is individually from about 0.1 to about 5 nm thick.

Aspect 55. The device of Aspect 50, wherein each sub-layer is individually from about 1 to about 5 nm thick.

Aspect 56. The device of any one of Aspects 50-55, wherein each sub-layer individually comprises a metal carbide, a metal boride, or a graded material thereof.

Aspect 57. The device of any one of Aspects 50-55, wherein each sub-layer individually comprises silicon carbide, boron carbide, beryllium carbide, aluminum carbide, magnesium carbide, aluminum boride, magnesium boride, beryllium boride, titanium boride, or a graded material thereof.

Aspect 58. The device of any one of Aspects 43-57, wherein the diamond layer comprises nanocrystalline diamond.

Aspect 59. The device of any one of Aspects 43-58, wherein the diamond layer is greater than or equal to 0.01 μm thick.

Aspect 60. The device of any one of Aspects 43-58, wherein the diamond layer is from about 0.01 μm to about 500 μm thick.

Aspect 61. The device of any one of Aspect 43-58, wherein the diamond layer is from about 0.01 μm to about 100 μm thick.

Aspect 62. The device of any one of Aspects 43-58, wherein the diamond layer is from about 0.01 μm to about 10 μm thick.

Aspect 63. The device of any one of Aspects 43-62, wherein the substrate layer comprises Al₂O₃, AlN, SiC, Si, GaN, BN, InN, Ga₂O₃, or a combination thereof.

Aspect 64. The device of any one of Aspects 43-63, wherein the channel layer comprises a Group III-nitride or alloy thereof.

Aspect 65. The device of any one of Aspects 43-63, wherein the channel layer comprises a Group III-nitride or alloy thereof selected from BN, AlN, GaN, InN, BAlN, AlGaN, InAlN, InGaN, ScAlN, InAlGaN, a graded material thereof, or a combination thereof.

Aspect 66. The device of any one of Aspects 43-63, wherein the channel layer comprises AlGaN in the form AlₓGa₁₋ₓN, wherein x is from 0.50 to about 0.95.

Aspect 67. The device of any one of Aspects 43-63, wherein the channel layer comprises AlGaN in the form AlₓGa₁₋ₓN, wherein x is from about 0.65 to about 0.85.

Aspect 68. The device of any one of Aspects 43-67, wherein the channel layer is from about 0.01 μm to about 20 μm thick.

Aspect 69. The device of any one of Aspects 43-67, wherein the channel layer is from about 0.01 μm to about 10 μm thick.

Aspect 70. The device of any one of Aspects 43-67, wherein the channel layer is from about 0.01 μm to about 1 μm thick.

Aspect 71. The device of any one of Aspects 43-70, wherein the plurality of semiconductor layers further comprises a nucleation layer between the substrate layer and the channel layer.

Aspect 72. The device of Aspect 71, wherein the nucleation layer is a graded layer comprising a Group III-nitride or alloy thereof selected from from BN, AlN, GaN, InN, BAlN, AlGaN, InAlN, InGaN, ScAlN, InAlGaN, or a combination thereof.

Aspect 73. The device of Aspect 71 or Aspect 72, wherein the nucleation layer is from about 1 nm to about 100 nm thick.

Aspect 74. The device of Aspect 71 or Aspect 72, wherein the nucleation layer is from about 1 nm to about 50 nm thick.

Aspect 75. The device of any one of Aspects 43-74, wherein the plurality of semiconductor layers further comprises a barrier layer on top of the channel layer.

Aspect 76. The device of Aspect 75, wherein the barrier layer comprises a Group III-nitride or alloy thereof selected from AlN, AlGaN, InGaN, InAlN, ScAlN, BAlN, InAlGaN, a graded material thereof, or a combination thereof.

Aspect 77. The device of Aspect 75 or Aspect 76, wherein the barrier layer is from about 5 nm to about 100 nm thick.

Aspect 78. The device of Aspect 75 or Aspect 76, wherein the barrier layer is from about 25 nm to about 75 nm thick.

Aspect 79. The device of any one of Aspects 43-78, wherein the thermal boundary resistance of the diamond/channel layer interface is less than about 15 m2K/GW.

Aspect 80. The device of any one of Aspects 43-78, wherein the thermal boundary resistance of the diamond/channel layer interface is less than about 10 m2K/GW.

Aspect 81. The device of any one of Aspects 43-78, wherein the thermal boundary resistance of the diamond/channel layer interface is from about 1 m2K/GW to about 15 m2K/GW.

Aspect 82. The device of any one of Aspects 43-78, wherein the thermal boundary resistance of the diamond/channel layer interface is from about 1 m2K/GW to about 10 m2K/GW.

Aspect 83. A method, comprising growing a plurality of semiconductor epitaxial layers on a substrate; depositing a gate material on the plurality of semiconductor epitaxial layers; depositing a phonon bridge layer on the plurality of semiconductor epitaxial layers; and growing a diamond layer on the phonon bridge layer.

Aspect 84. The method of Aspect 83, wherein the semiconductor epitaxial layers are grown using metal-organic chemical vapor deposition, hydride vapor-phase epitaxy, or molecular beam epitaxy.

Aspect 85. The method of Aspect 83 or Aspect 84, wherein the phonon bridge layer is deposited by sputtering, chemical vapor deposition, atomic layer deposition, pulsed laser deposition, or electron-beam evaporation.

Aspect 86. The method of Aspect 83, wherein growing the diamond layer comprises ultrasonic deposition of diamond nano crystals, forming a diamond seeded layer; and growing the diamond layer from the diamond seeded layer by chemical vapor deposition, microwave-plasma chemical vapor deposition, or hot filament chemical vapor deposition.

Aspect 87. The method of Aspect 86, wherein the diamond layer is grown from the diamond seeded layer by laser-plasma chemical vapor deposition, microwave-plasma chemical vapor deposition, or hot-filament chemical vapor deposition

From the foregoing, it will be seen that aspects herein are well adapted to attain all the ends and objects hereinabove set forth together with other advantages which are obvious and which are inherent to the structure.

While specific elements and steps are discussed in connection to one another, it is understood that any element and/or steps provided herein is contemplated as being combinable with any other elements and/or steps regardless of explicit provision of the same while still being within the scope provided herein.

It will be understood that certain features and subcombinations are of utility and may be employed without reference to other features and subcombinations. This is contemplated by and is within the scope of the claims.

Since many possible aspects may be made without departing from the scope thereof, it is to be understood that all matter herein set forth or shown in the accompanying drawings and detailed description is to be interpreted as illustrative and not in a limiting sense.

It is also to be understood that the terminology used herein is for the purpose of describing particular aspects only and is not intended to be limiting. The skilled artisan will recognize many variants and adaptations of the aspects described herein. These variants and adaptations are intended to be included in the teachings of this disclosure and to be encompassed by the claims herein.

Now having described the aspects of the present disclosure, in general, the following Examples describe some additional aspects of the present disclosure. While aspects of the present disclosure are described in connection with the following examples and the corresponding text and figures, there is no intent to limit aspects of the present disclosure to this description. On the contrary, the intent is to cover all alternatives, modifications, and equivalents included within the spirit and scope of the present disclosure.

### G. EXAMPLES

The following examples are put forth so as to provide those of ordinary skill in the art with a complete disclosure and description of how the compounds, compositions, articles, devices and/or methods claimed herein are made and evaluated and are intended to be purely exemplary of the disclosure and are not intended to limit the scope of what the inventors regard as their disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric.

### 1. Experimental Methods

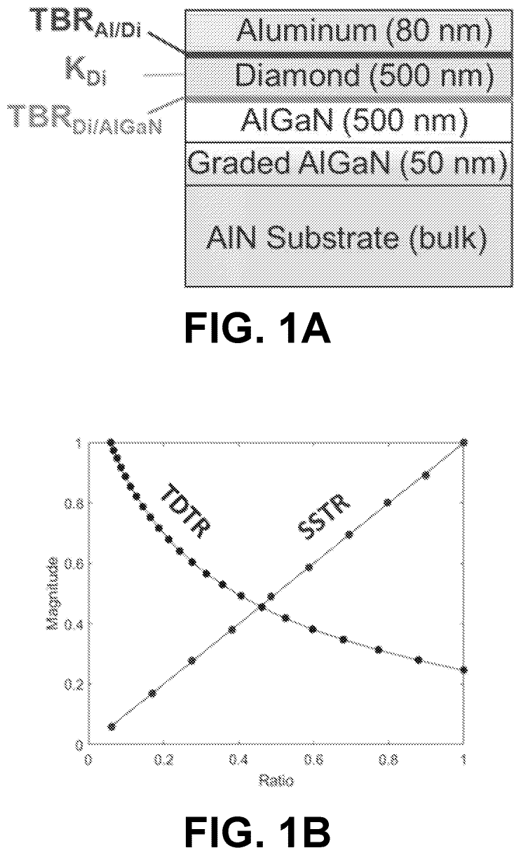

The structure of the grown samples is shown in FIG. 1A. The epilayer structure for the study was deposited on physical vapor transport (PVT)-grown 400 μm thick (0001) orientation and 0.25° miscut, commercially available 2-inch bulk AlN substrates (threading dislocation density, TDD of about 103 cm-2) from Hexatech.[13] The growths were done on the Al-face of the substrate.

Prior to epitaxy, the as-received chemical-mechanical polished (CMP) substrate was subjected to acid-based surface preparation, hydrogen annealing, and nitridation.[14] Subsequently, using MOCVD, epilayer structures as shown in FIG. 1A were deposited over the AlN substrate. All the growths were carried out at 1100-1200° C. and 40 torr using trimethylaluminum (TMA), trimethylgallium (TMG), and ammonia (NH3) as the precursors. All the layers were undoped. AlN nucleation layers were grown at 1200° C., whereas high-Al AlₓGa₁₋ₓN (x>0.65) were grown at 1160° C. A growth rate of 150 nm/h was achieved at the AlGaN growth conditions.[15]

The increasing lattice mismatch with increasing Ga-content in AlGaN alloy engenders large compressive stress of several GPa, resulting in large wafer bow for the growth of thick AlGaN epilayers on AlN substrates. Of the few reports on AlGaN growth on native AlN substrates, Dalmau et al. observed 8% relaxation for a 400 nm thick Al0.65Ga0.35N layer.[16] Grandusky et al. observed pseudomorphic growth of Al_{0.6}Ga_{0.4}N until a thickness of 0.5 μm. [17] At larger thicknesses, they observed relaxation and an increase in TD density, which possibly formed via the interaction between misfit dislocations. Ren et al. reported the use of superlattice buffer layers for strain relief and found an inverse relationship between the degree of relaxation and surface roughness. [18] Linearly graded AlGaN was used as a potential strain relief layer while concomitantly maintaining the low TD density. For the characterization of the epilayers in this study, the AFM surface analysis was done using a Veeco instrument both for the starting AlN substrate (after surface preparation), and the as grown heterostructure. The AlN substrate shows uniform parallel steps with root mean square (RMS) roughness of about 0.1 nm. For thick AlGaN layers, the RMS roughness was 0.24-0.33 nm for different compositions.

Boron carbide (B₄C) and silicon carbide (SiC) layers were sputtered in an AJA International sputtering system with BAC and SiC targets indium-bonded to a copper base (Kurt J. Lesker). Both the SiC and B₄C layers had nominal thickness of 2 nm each. SiC was sputtered at room temperature, 30 W/in2 RF power, 3 mTorr pressure, and 40 sccm Ar flow. B₄C was sputtered at room temperature, 20 W/in2 RF power, 3 mTorr pressure, 40 sccm Ar flow. For the dual-layer deposition, the SiC sputtering process was followed by B₄C in situ for a nominal thickness of 2 nm for each layer. Ellipsometry measurement of this stack, referred to as SiC/B₄C henceforth, deposited on a Si control sample, suggested a total thickness of 4.5 nm and a 2.04 refractive index. Prior to sputtering, the AlGaN samples were megasonic cleaned followed by etching in 10:1 dilute HCl for 30 seconds, 10:1 buffered oxide etchant for 60 seconds, and placed under vacuum less than 30 minutes after acid cleaning. Nanocrystalline diamond growth was performed in an Astex 1.5 KW microwave assisted plasma CVD reactor at 750 C, 800 W power, 15 Torr pressure, 900/3.0 sccm H₂/CH₄ gas ratio, resulting in a 0.52 μm thick NCD layer. Additional characterization was performed via Nomarski microscopy, AFM imaging, and Raman spectroscopy.

Two laser-based pump-probe measurement techniques were used for the measurement of thermal properties: Time Domain Thermoreflectance (TDTR) and Steady State Thermoreflectance (SSTR). In both techniques, a laser beam heats the sample (pump beam) while a second beam (probe) monitors the pump-induced temperature rise. In both cases, the data is fit to an analytical model for the transient heat equation for a multi-layered sample, allowing extraction of unknown thermal properties. In TDTR, pulsed beams are used, and the arrival of the pump and probe pulses is temporally offset, allowing reconstruction of a time-dependent thermal decay. In SSTR, the amplitude of the temperature rise is recorded under varying pump powers, where the slope can be considered roughly inversely proportional to the thermal resistivity within the measured region. Both techniques require the use of a thin metal transducer (80 nm aluminum in this case) to isolate the deposition of heat and probe thermoreflectance signal to the surface of the sample. Similarly, for SSTR, precise values for pump absorption or thermoreflectance coefficients are not required, as a reference sample with known properties and an identical surface (transducer material and surface finish) is used to account for these scaling terms. For the measurements, an additional reference sample was used to determine the substrate thermal properties, four-point probe electrical resistivity measurements were used to find the transducer thermal conductivity, and picosecond laser ultrasonics were used to determine the transducer thickness. Within the TDTR and SSTR thermal models, the material properties of each layer for the fabricated samples are shown in Table I.

In the Al/Diamond/AlGaN/AlN samples, one focus was on determining the effective thermal boundary resistance of the Diamond/Carbide/AlGaN junction (TBR_{Di/AlGaN}), as labeled in FIG. 1A. However, due to the thickness of the Diamond (size effects) and its crystallinity (defect effects), also needed to determine was the thermal conductivity of Diamond (K_{Di}) and the thermal boundary resistance of the Aluminum/Diamond interface (TBR_{Ai/Di}). The sensitivity of each measurement technique employed in this study to these unknown thermal parameters is compared in the supplemental information. It is worth noting that both techniques exhibit sensitivity to all three aforementioned parameters.

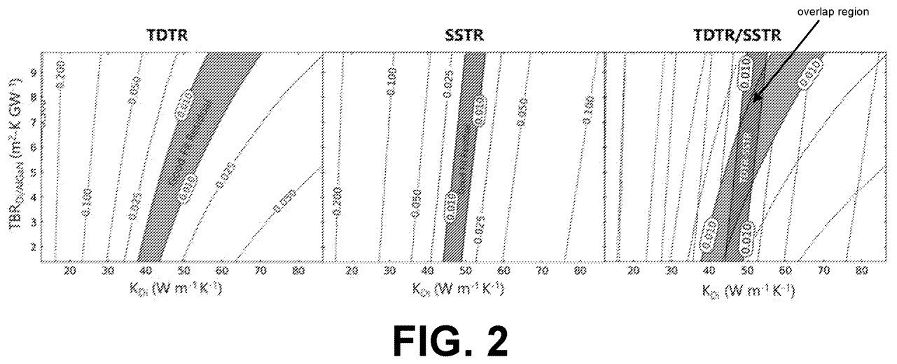

Attempting to fit for all three unknown parameters using only TDTR data poses a significant challenge. A wide range of values for the thermal boundary resistance (TBR_{Di/AlGAN}) can lead to acceptable fits to the measured data. To identify and visualize these acceptable values, various ranges for the unknown parameters of the system were explored and the residual between the curve produced by each parameter combination and the measured data was calculated. A threshold for the quality of the fit is selected, such as 1% in the case of exceptionally clean data, to constrain the acceptable values derived from the measurements. Conceptually, for the three unknown parameters, this process results in a 3D volume of acceptable fitted values. However, for simplicity, we will hold TBR_{Di/AlGaN} constant and graph the range of acceptable values for K_{Di} and TBR_{Di/AlGaN}, representing a 2D slice shown in FIG. 2.

Notably, the contours plotted for SSTR and TDTR exhibit different shapes. Additionally, a small area of intersection is observed where the contours for SSTR and TDTR overlap. By simultaneously fitting both TDTR and SSTR measured data using a hybrid fitting scheme, the range of acceptable fitted values obtained is limited to those that yield acceptable fits for both SSTR and TDTR datasets (the intersected region). An example dataset and fit are illustrated in FIG. 1B. Employing this hybrid fitting approach significantly reduces the uncertainty in the fitted values of the unknown parameters. A similar principle is applied when others fit to the ratio and magnitude of TDTR measurements or during multi-frequency TDTR measurements.

The thermal model and numerical fitting algorithm are tasked with determining a combination of three unknowns that yields an acceptable fit for both TDTR and SSTR datasets. The fitting process utilizes existing numerical tools, such as Python's scipy minimize function, where the residual is calculated independently for each dataset and model. The maximum residual, representing the worst fit between SSTR and TDTR, is then passed to the minimization function to ensure that the worst-fitting dataset drives the overall fit. Additionally, adopt the residual value approach is adopted, as outlined in Cahill et al. (i.e. 1% residual), instead of using a mean squared error, to avoid potential issues associated with differently weighting datasets due to variations in data scaling or dataset lengths.

It is important to note that this fitting procedure differs slightly from that used for fitting TDTR data collected at multiple modulation frequencies. In the case of multi-frequency TDTR fitting, the datasets can be directly appended to each other, or a surface-fitting algorithm can be employed. While this approach is also feasible for TDTR/SSTR hybrid fitting, it is essential to consider the scaling of the SSTR data to ensure compatibility with the TDTR datasets.

### 2. Results and Discussion

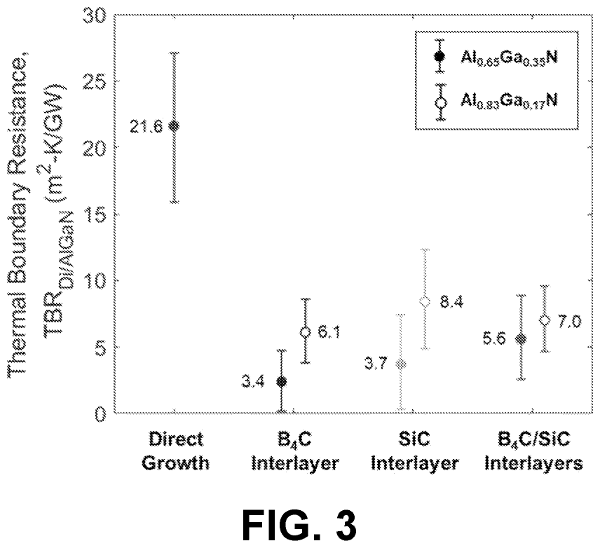

The measured values of TBR_{Di/AlGaN} from simultaneous fitting of SSTR/TDTR measurements are presented in FIG. 3. The fitted values of TBR_{AVDi} for each sample were consistently found to be 28.2±1.5 m²K/GW, matching TBR values found in literature. Meanwhile, the fitted values K_{Di} for both Aluminum concentrations of AlGaN (i.e., 65% and 83% Aluminum) were found to be 49.4±2.1 and 74.9±1.3 W/m-K, respectively.

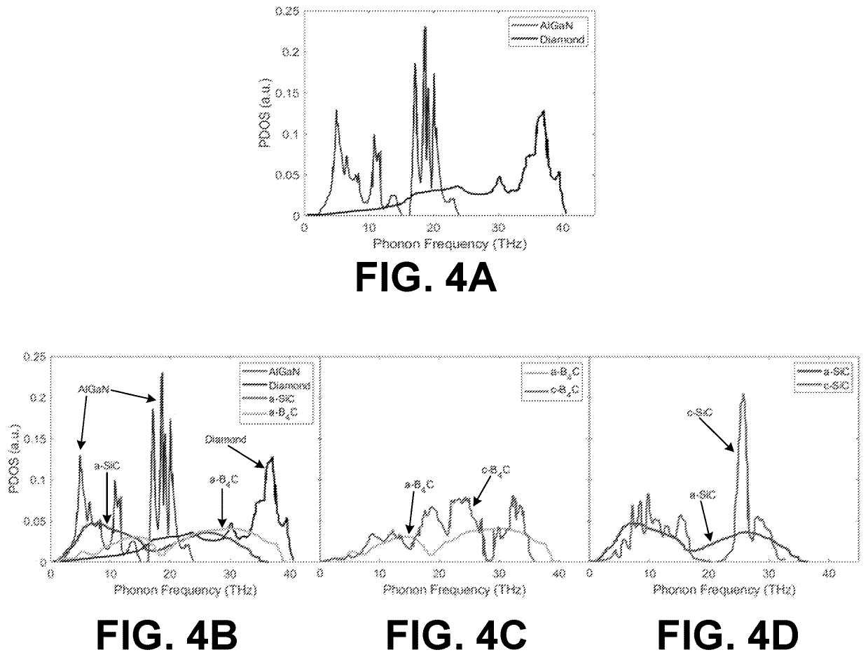

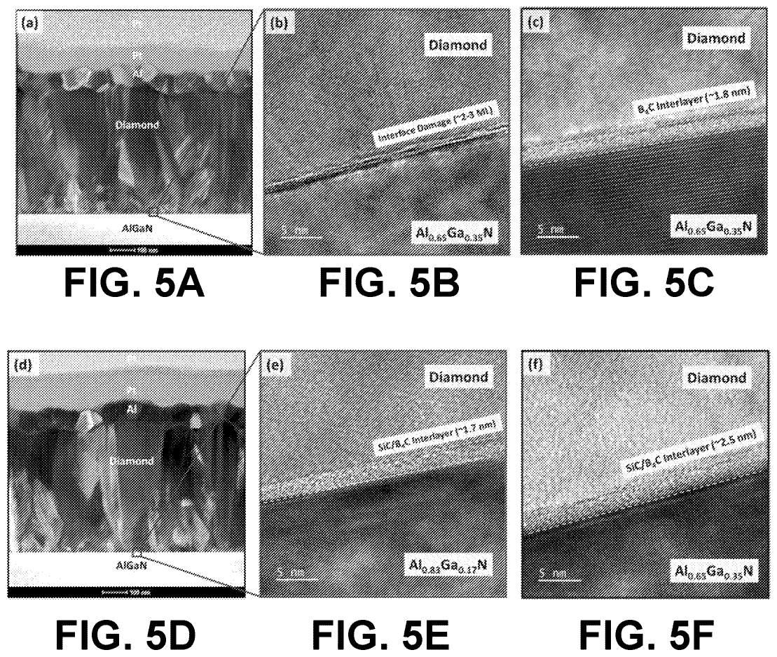

Direct MPCVD Diamond growth on AlGaN yielded a thermal boundary resistance (TBR_{Di/AlGaN}) of 21.6 m²K/GW. This substantial value can be attributed, in part, to the weak van-der-Waals bonding between Diamond and AlGaN and the absence of phonon frequency overlap between the two materials, as illustrated in FIG. 4A. Furthermore, as shown in FIG. 5B, STEM imaging revealed structural damage and disorder at the Diamond-AlGaN interface, likely caused by high-temperature H-plasma exposure deteriorating the AlGaN surface. Structural disorder at the interface may create scattering sites for phonons, which in turn may increase the thermal resistance of the interface.

It is noteworthy that the inclusion of carbide interlayers (i.e., B₄C, SiC, and B₄C/SiC) may effectively reduce TBR_{Di/AlGaN} for samples, shown in FIG. 3. A TBR_{Di/AlGaN} of 3.4 m²K/GW and 3.7 m²K/GW for Al_{0.65}Ga_{0.35}N samples was measured via the inclusion of BAC and SiC interlayers, respectively, a new record for diamond/AlGaN interfaces. For the Al_{0.83}Ga_{0.17}N samples, 6.1 m²K/GW and 8.4 m²K/GW was measured for B₄C and SiC interlayers, respectively. This reduction may be attributed to several factors. First, the carbide interlayers provide vibrational bridging for phonons transporting between Diamond and AlGaN via the introduction of intermediate frequency phonon modes, as seen by their phonon density of states in FIG. 4B. Additionally, FFT characterization of the STEM images, shown in FIGS. 5B-5F, revealed all carbide interlayers to be amorphous and have a thickness between 1.7-2.5 nm. Notably, amorphous materials may be less confining on the phonon modes than their crystalline counterparts, enabling phonon mode conversions and broadening of the phonon density of states (improving PDOS overlap with Diamond and AlGaN), seen by the amorphous/crystalline comparison in FIGS. 4C-4D). [19-21] Both of these factors may facilitate greater phonon passage across the Diamond/Carbide/AlGaN junction, lowering TBR_{Di/AlGaN}. It is speculated that amorphous B₄C interlayers provided the lowest TBR_{Di/AlGaN} values of all samples due to having the better phonon density of states overlap with diamond at high phonon frequencies than amorphous SiC, seen in FIG. 4A.

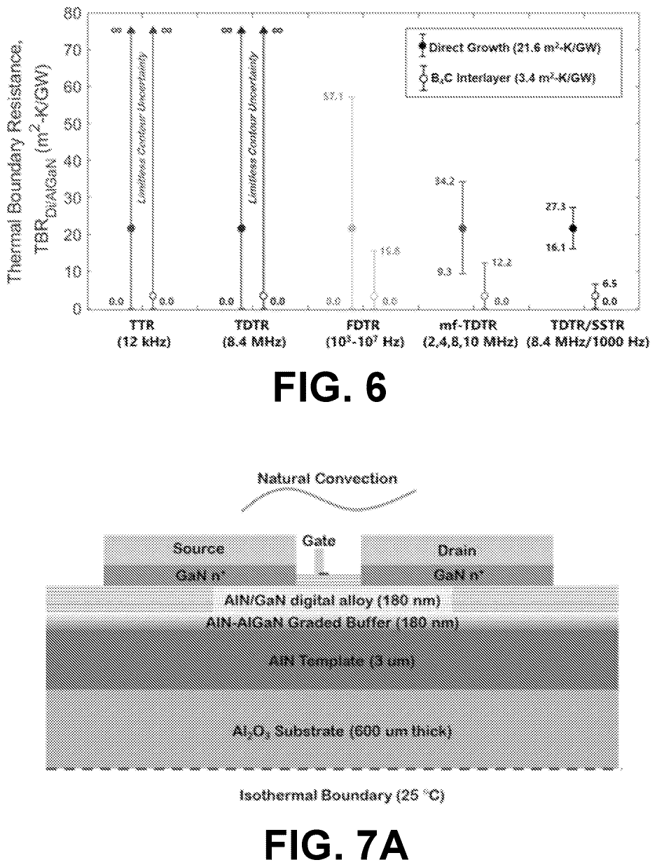

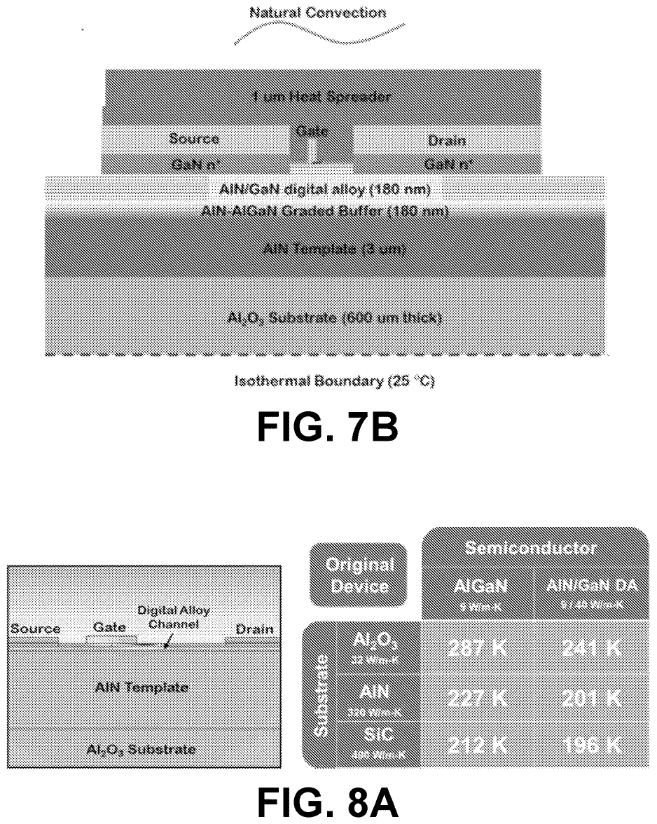

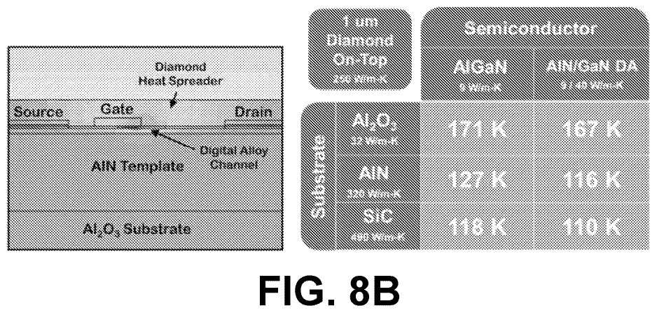

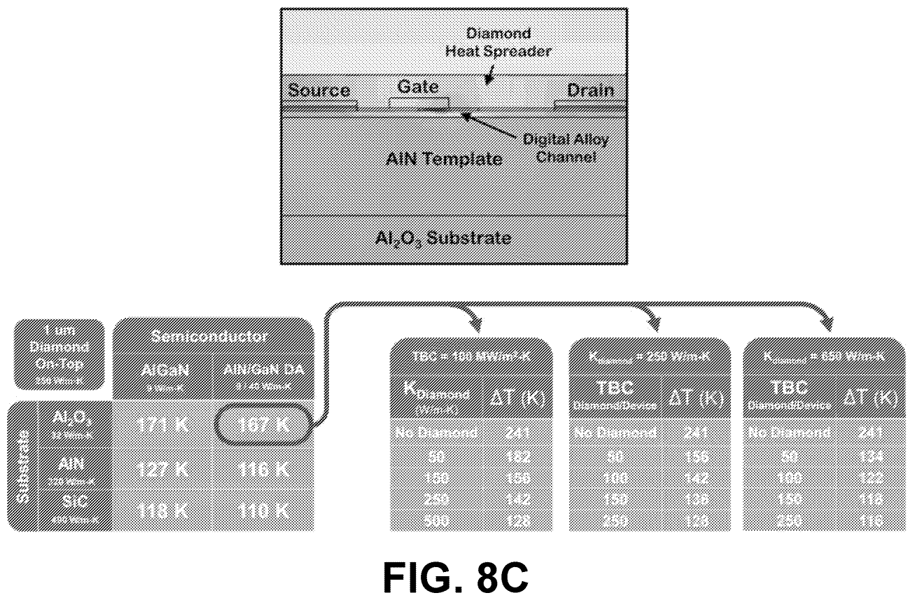

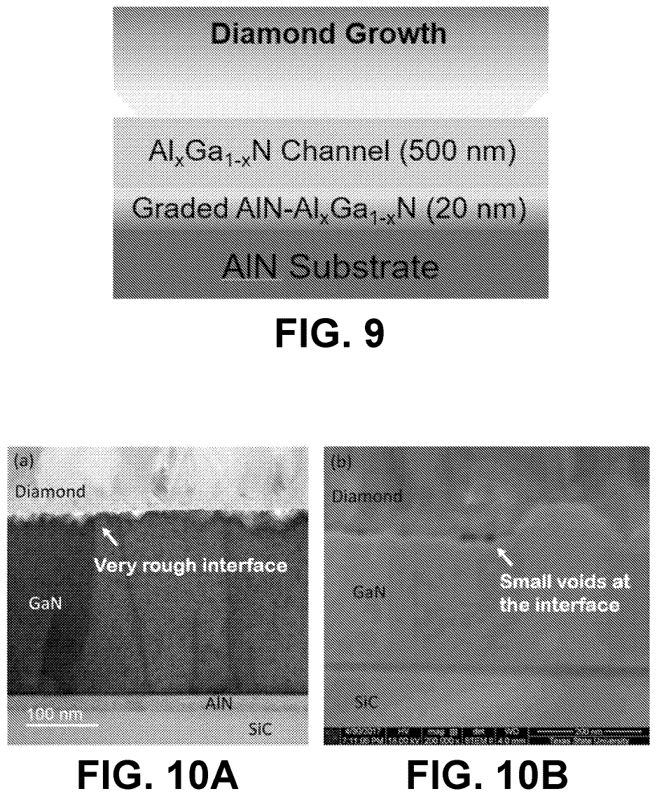

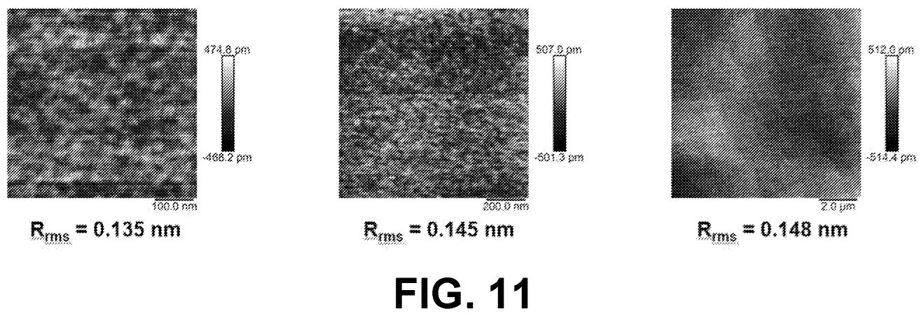

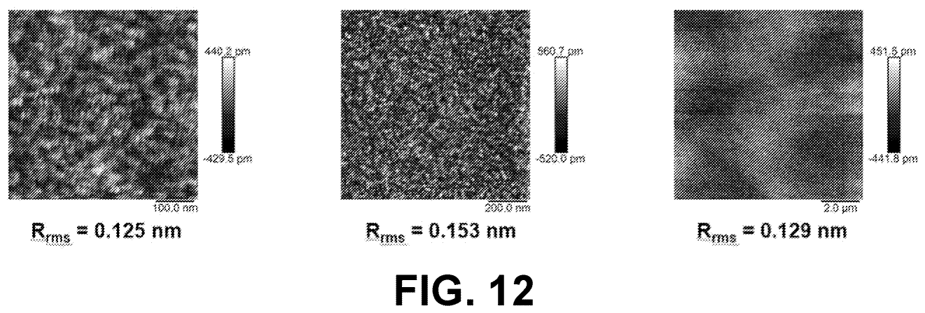

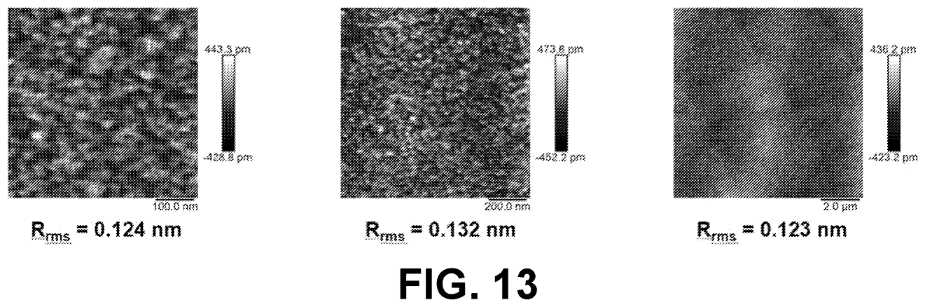

The thermal measurements discussed above are groundbreaking, not only shedding light on strategies for implementing diamond layers atop AlGaN devices (via carbide interlayers), but also by capturing buried thermal resistances that conventional thermoreflectance techniques struggle to detect. To underscore this significance, an analysis comparing the contour uncertainty associated with prominent thermoreflectance methods documented in the literature with these experimental measurements is presented. Specifically, the direct-growth Diamond/AlGaN sample (no interlayer, the largest TBR_{Di/AlGaN} observed in this study) and the B₄C interlayer sample (65% Al concentration in AlGaN, the smallest TBR_{Di/AlGaN} observed in this study), with comparisons illustrated in FIG. 6 were examined.

First, Transient thermoreflectance (TTR) and Time-domain thermoreflectance (TDTR) techniques both failed to measure TBR_{Di/AlGaN} due to a phenomena that we here define as “Limitless Contour Uncertainty.” Using TTR or TDTR systems to measure any of the samples in this paper may result in datasets with an unlimited possible combination of fitted values for TBR_{AVDi}, K_{Di}, and TBR_{Di/AlGaN} that can produce a curve fitting the data well (i.e., residual error ≤1%). This presents a silent but serious danger to the thermal characterization community. Users not quantifying contour uncertainty for their system, may attempt to fit their measured data, just to extract values for TBR_{AVDi}, K_{Di}, and TBR_{Di/AlGaN} which may be purely arbitrary and meaningless. For such a dataset, it is still possible to calculate the uncertainty of fitted values by propagating uncertainty in modeling parameters. However, in a Limitless Contour Uncertainty system, the values of fitted parameters and their propagated uncertainties may still be meaningless.

The temporal resolution of TTR may be insufficient for measuring the samples due to its single-pulse response nature, resembling an exponential decay. Consequently, attempting to fit three parameters using a single exponential time constant may not be feasible, resulting in a myriad of fitted parameter combinations producing low residual error curve fits to the data.

Time-domain Thermoreflectance (TDTR) (8.4 MHz modulation frequency) is limited in the thermal penetration depth, approximated by Eq. 1.

$${d}_{p , z} = \sqrt{\frac{{K}_{z}}{π {f}_{m} C}} = \sqrt{\frac{\frac{49.3 W}{m} - K}{( π ) ( 8.4 e 6 Hz ) ( \frac{1.83 e 6 J}{{m}^{3}} - K )}} = 1.01 µm \qquad Eq . 1$$

While TBR_{Di/AlGaN} is within the thermal penetration depth of TDTR, making it slightly sensitive to its value, it's not a dominant thermal resistance. TDTR may be more sensitive to shallow large-value thermal resistances, like the thermal resistance of the diamond layer and TBR_{AVDi}.

Frequency Domain Thermoreflectance (FDTR) encompasses a spectrum of thermal penetration depths, ranging from the beam radii (3.5 mm) at low frequencies to d_{p,z} at high frequencies. However, the influence of each thermal property on phase data at low frequencies may be minimal, resulting in limited sensitivity to buried thermal resistances like TBR_{Di/AlGaN}. Thus, large contour uncertainty for FDTR measurements of TBR_{Di/AlGaN} is observed.

Multi-frequency-TDTR may be robust at gaining sensitivity to buried thermal resistances via measuring the temporal response at different frequencies and different thermal penetration depths. However, a limitation of mf-TDTR is there exists a lower limit to modulation frequency at which data can be collected and still be clean. As such, mf-TDTR fitting resulted in the second lowest contour uncertainty, unable to probe buried thermal resistances as effectively as SSTR.

Lastly, the hybrid technique of SSTR-TDTR introduced herein capitalizes on the strengths of both measurement techniques. The SSTR measurement utilizes non-normalized magnitude data to fit at very low modulation frequencies (1000 Hz), resulting in deep thermal penetration depths and heightened sensitivity to buried thermal resistances. Meanwhile, the TDTR measurement utilizes a temporal response at a high modulation frequency (8.4 MHz), resulting in lower thermal penetration depths and sensitivity to thermal resistances near the surface of the sample. As a result, SSTR-TDTR hybrid fitting produced the smallest contour uncertainty of the five techniques mentioned. This study elucidates the challenges associated with contour uncertainty during the measurement of buried interfaces and pioneers a hybrid fitting scheme that combines SSTR-TDTR to mitigate these challenges. This methodological advancement may be useful for thermal measurements involving samples with numerous unknown parameters, where contour uncertainty poses a formidable obstacle.

### H. REFERENCES

References are cited herein throughout using the format of reference number(s) enclosed by brackets corresponding to one or more of the following numbered references. For example, citation of references numbers 1 and 2 immediately herein below would be indicated in the disclosure as [1, 2].
[Ref. 1] R. J. Kaplar, A. A. Allerman, A. M. Armstrong, M. H. Crawford, J. R. Dickerson, A. J. Fischer, A. G. Baca, and E. A. Douglas, Review—ultra-wide-bandgap algan power electronic devices, ECS Journal of Solid State Science and Technology 6, Q3061-Q3066 (2016).
[Ref. 2] A. G. Baca, A. M. Armstrong, B. A. Klein, A. A. Allerman, E. A. Douglas, and R. J. Kaplar, Al-rich algan based transistors, Journal of Vacuum Science amp; Technology A: Vacuum, Surfaces, and Films 38, 10.1116/1.5129803 (2020).
[Ref. 3] T. Nanjo, A. Imai, Y. Suzuki, Y. Abe, T. Oishi, M. Suita, E. Yagyu, and Y. Tokuda, Algan channel hemt with extremely high breakdown voltage, IEEE Transactions on Electron Devices 60, 1046-1053 (2013).
[Ref. 4] J. Y. Tsao, S. Chowdhury, M. A. Hollis, D. Jena, N. M. Johnson, K. A. Jones, R. J. Kaplar, S. Rajan, C. G. Van de Walle, E. Bellotti, C. L. Chua, R. Collazo, M. E. Coltrin, J. A. Cooper, K. R. Evans, S. Graham, T. A. Grotjohn, E. R. Heller, M. Higashiwaki, M. S. Islam, P. W. Juodawlkis, M. A. Khan, A. D. Koehler, J. H. Leach, U. K. Mishra, R. J. Nemanich, R. C. N. Pilawa-Podgurski, J. B. Shealy, Z. Sitar, M. J. Tadjer, A. F. Witulski, M. Wraback, and J. A. Simmons, Ultrawide-bandgap semiconductors: Research opportunities and challenges, Advanced Electronic Materials 4, 10.1002/aelm.201600501 (2017).
[Ref. 5] A. Nigam, T. N. Bhat, S. Rajamani, S. B. Dolmanan, S. Tripathy, and M. Kumar, Effect of self-heating on electrical characteristics of algan/gan hemt on si (111) substrate, AIP Advances 7, 10.1063/1.4990868 (2017).
[Ref. 6] R. Bothra, Modelling and simulation of self heating in GaN based high electron mobility transistors (HEMTs), International Journal of Advanced Applied Physics Research (2017).
[Ref. 7] Y. Gu, Y. Zhang, B. Hua, X. Ni, Q. Fan, and X. Gu, Interface engineering enabling next gen-eration gan-on-diamond power devices, Journal of Electronic Materials 50, 4239-4249 (2021).
[Ref. 8] T. Gerrer, J. Pomeroy, F. Yang, D. Francis, J. Carroll, B. Loran, L. Witkowski, M. Yarbor-ough, M. J. Uren, and M. Kuball, Thermal design rules of algan/gan-based microwave tran-sistors on diamond, IEEE Transactions on Electron Devices 68, 1530 (2021).
[Ref. 9] J. G. Felbinger, M. V. S. Chandra, Y. Sun, L. F. Eastman, J. Wasserbauer, F. Faili, D. Babic, D. Francis, and F. Ejeckam, Comparison of gan hemts on diamond and sic substrates, IEEE Electron Device Letters 28, 948 (2007).
[Ref. 10] M. Malakoutian, C. Ren, K. Woo, H. Li, and S. Chowdhury, Development of polycrystalline diamond compatible with the latest n-polar gan mm-wave technology, Crystal Growth amp; Design 21, 2624-2632 (2021).
[Ref. 11] L. Arivazhagan, A. Jarndal, and D. Nirmal, Gan hemt on si substrate with diamond heat spreader for high power applications, Journal of Computational Electronics 20, 873-882 (2021).
[Ref. 12] O. Babchenko, J. Dzuba, T. Lalinsky′, M. Vojs, A. Vincze, T. I′z′ak, and G. Vanko, Stability of algan/gan heterostructures after hydrogen plasma treatment, Applied Surface Science 395, 92-97 (2017).
[Ref. 13] K. Hussain, A. Mamun, R. Floyd, M. D. Alam, M. E. Liao, K. Huynh, Y. Wang, M. Goorsky, M. Chandrashekhar, G. Simin, and A. Khan, High figure of merit extreme bandgap al0.87ga0.13n-al0.64ga0.36n heterostructures over bulk aln substrates, Applied Physics Ex-press 16, 014005 (2023).
[Ref. 14] A. Mamun, K. Hussain, R. Floyd, M. D. Alam, M. Chandrashekhar, G. Simin, and A. Khan, A10.64ga0.36n channel moshfet on single crystal bulk aln substrate, Applied Physics Express 16, 061001 (2023).
[Ref. 15] S. Washiyama, P. Reddy, F. Kaess, R. Kirste, S. Mita, R. Collazo, and Z. Sitar, A thermo-dynamic supersaturation model for the growth of aluminum gallium nitride by metalorganic chemical vapor deposition, Journal of Applied Physics 124, 10.1063/1.5045058 (2018).
[Ref. 16] R. Dalmau, B. Moody, R. Schlesser, S. Mita, J. Xie, M. Feneberg, B. Neuschl, K. Thonke, R. Collazo, A. Rice, J. Tweedie, and Z. Sitar, Growth and characterization of aln and algan epitaxial films on aln single crystal substrates, Journal of The Electrochemical Society 158, H530 (2011).
[Ref. 17] J. Grandusky, J. Smart, M. Mendrick, L. Schowalter, K. Chen, and E. Schubert, Pseudomor-phic growth of thick n-type alxga1xn layers on low-defect-density bulk aln substrates for uv led applications, Journal of Crystal Growth 311, 2864-2866 (2009).
[Ref. 18] Z. Ren, Q. Sun, S.-Y. Kwon, J. Han, K. Davitt, Y. K. Song, A. V. Nurmikko, H.-K. Cho, W. Liu, J. A. Smart, and L. J. Schowalter, Heteroepitaxy of algan on bulk aln substrates for deep ultraviolet light emitting diodes, Applied Physics Letters 91, 10.1063/1.2766841 (2007).
[Ref. 19] L. Yang, B. Latour, and A. J. Minnich, Phonon transmission at crystalline-amorphous in-terfaces studied using mode-resolved atomistic green's functions, Physical Review B 97, 10.1103/physrevb.97.205306 (2018).
[Ref. 20] Y. M. Beltukov, D. A. Parshin, V. M. Giordano, and A. Tanguy, Propagative and diffusive regimes of acoustic damping in bulk amorphous material, Physical Review E 98, 10.1103/phys-reve.98.023005 (2018).
[Ref. 21] W. Lv and A. Henry, Non-negligible contributions to thermal conductivity from localized modes in amorphous silicon dioxide, Scientific Reports 6, 10.1038/srep35720 (2016).

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

1. A device, comprising:
a plurality of semiconductor layers;
a phonon bridge layer formed on the plurality of semiconductor layers;
a gate electrode set into the phonon bridge layer and in contact with a surface of the plurality of semiconductor layers; and
a diamond layer formed over the phonon bridge layer;
wherein the phonon bridge layer comprises materials that have a speed of sound in-between the speed of sound for the diamond layer and the speed of sound of the semiconductor layer that is in contact with the phonon bridge layer.

2. (canceled)

3. (canceled)

4. (canceled)

5. (canceled)

6. The device of claim 1, wherein the phonon bridge layer comprises a metal carbide, a metal boride, or a graded material thereof.

7. (canceled)

8. (canceled)

9. (canceled)

10. (canceled)

11. (canceled)

12. (canceled)

13. (canceled)

14. (canceled)

15. (canceled)

16. (canceled)

17. The device of claim 1, wherein the diamond layer comprises nanocrystalline diamond.

18. (canceled)

19. (canceled)

20. (canceled)

21. (canceled)

22. The device of claim 1, wherein the plurality of semiconductor layers comprises at least a substrate layer and a channel layer.

23. The device of claim 22, wherein the substrate layer comprises Al₂O₃, AlN, SiC, Si, GaN, BN, InN, Ga₂O₃, or a combination thereof.

24. (canceled)

25. (canceled)

26. (canceled)

27. (canceled)

28. (canceled)

29. (canceled)

30. (canceled)

31. The device of claim 22, wherein the plurality of semiconductor layers further comprises a nucleation layer between the substrate layer and the channel layer.

32. The device of claim 31, wherein the nucleation layer is a graded layer comprising a Group III-nitride or alloy thereof selected from from BN, AlN, GaN, InN, BAlN, AlGaN, InAlN, InGaN, ScAlN, InAlGaN, or a combination thereof.

33. (canceled)

34. (canceled)

35. The device of claim 1, wherein the plurality of semiconductor layers further comprises a barrier layer on top of the channel layer.

36. The device of claim 35, wherein the barrier layer comprises a Group III-nitride or alloy thereof selected from AlN, AlGaN, InGaN, InAlN, ScAlN, BAlN, InAlGaN, a graded material thereof, or a combination thereof.

37. (canceled)

38. (canceled)

39. The device of claim 1, wherein the thermal boundary resistance of the diamond/semiconductor layers interface is less than about 15 m²K/GW.

40. (canceled)

41. (canceled)

42. (canceled)

43. A device, comprising:
a plurality of semiconductor layers, comprising a substrate layer, a channel layer, and a barrier layer, wherein the channel layer is between the substrate layer and the barrier layer;
a phonon bridge layer formed on the barrier layer;
a gate electrode set into the phonon bridge layer and in contact with at least one of the plurality of semiconductor layers;
a drain electrode set into the phonon bridge layer and in contact with at least one of the plurality of semiconductor layers;
a source electrode set into the phonon bridge layer and in contact with at least one of the plurality of semiconductor layers;
a diamond layer formed over the phonon bridge layer;
wherein the phonon bridge layer comprises materials that have a speed of sound in-between the speed of sound for the diamond layer and the speed of sound for the channel layer.

44. (canceled)

45. (canceled)

46. (canceled)

47. The device of claim 43, wherein the phonon bridge layer is from about 0.1 nm to about 5 nm thick.

48. (canceled)

49. The device of claim 43, wherein the phonon bridge layer comprises silicon carbide, boron carbide, beryllium carbide, aluminum carbide, magnesium carbide, aluminum boride, magnesium boride, beryllium boride, titanium boride, or a graded material thereof.

50. The device of claim 43, wherein the phonon bridge layer comprises from 1 to 4 sub-layers.

51. (canceled)

52. (canceled)

53. (canceled)

54. (canceled)

55. (canceled)

56. (canceled)

57. The device of claim 50, wherein each sub-layer individually comprises silicon carbide, boron carbide, beryllium carbide, aluminum carbide, magnesium carbide, aluminum boride, magnesium boride, beryllium boride, titanium boride, or a graded material thereof.

58. (canceled)

59. (canceled)

60. (canceled)

61. (canceled)

62. The device of claim 43, wherein the diamond layer is from about 0.01 μm to about 10 μm thick.

63. The device of claim 43, wherein the substrate layer comprises Al₂O₃, AlN, SiC, Si, GaN, BN, InN, Ga₂O₃, or a combination thereof.

64. (canceled)

65. The device of claim 43, wherein the channel layer comprises a Group III-nitride or alloy thereof selected from BN, AlN, GaN, InN, BAlN, AlGaN, InAlN, InGaN, ScAlN, InAlGaN, a graded material thereof, or a combination thereof.

66. (canceled)

67. (canceled)

68. (canceled)

69. (canceled)

70. (canceled)

71. (canceled)

72. (canceled)

73. (canceled)

74. (canceled)

75. (canceled)

76. (canceled)

77. (canceled)

78. (canceled)

79. (canceled)

80. (canceled)

81. (canceled)

82. The device of claim 43, wherein the thermal boundary resistance of the diamond/channel layer interface is from about 1 m²K/GW to about 10 m²K/GW.

83. A method, comprising:
growing a plurality of semiconductor epitaxial layers on a substrate;
depositing a gate material on the plurality of semiconductor epitaxial layers;
depositing a phonon bridge layer on the plurality of semiconductor epitaxial layers; and
growing a diamond layer on the phonon bridge layer.

84. (canceled)

85. (canceled)

86. (canceled)

87. (canceled)
